(19) United States
(12) Patent Application Publication
(10) Pub. No.: US 2006/0170074 A1
(43) Pub. Date: Aug. 3, 2006

(54) Semiconductor device

(76) Inventor: Yoshikazu Ibara, Gifu-ken (JP)

Correspondence Address: MCDERMOTT WILL & EMERY LLP, 600 13TH STREET, N.W., WASHINGTON, DC, 20005-3096, US

(21) Appl. No.: 11/319,212

(22) Filed: Dec. 28, 2005

(30) Foreign Application Priority Data
Dec. 28, 2004 (JP) 2004-380115
Feb. 18, 2005 (JP) 2005-041470
Dec. 16, 2005 (JP) 2005-362738

(51) Int. Cl. H01L 27/082

(52) U.S. Cl. 257/565

(57) ABSTRACT

A semiconductor substrate includes an element isolation film arranged in a semiconductor substrate. An active region surrounded by the element isolation film functions as a collector layer. A conductive layer, which includes an alloy layer, is arranged on the active region. An emitter layer is arranged on the conductive layer. An emitter electrode is arranged on the emitter layer. A first film covers the side surface of the emitter electrode. A p⁺ diffusion layer is located adjacent to the conductive layer. An impurity region extends between the first alloy layer and the element isolation film in the active region. The boundary between the p⁺ diffusion layer and the alloy layer is located on an impurity region.

### CROSS-REFERENCE TO RELATED APPLICATIONS

This application is based upon and claims the benefit of priority from prior Japanese Patent Application No. 2004-380115, filed on Dec. 28, 2004, Japanese Patent Application No. 2005-041470, filed on Feb. 18, 2005, and Japanese Patent Application No. 2005-362738, filed on Dec. 16, 2005, the entire contents of which are incorporated herein by reference.

### BACKGROUND OF THE INVENTION

The present invention relates to a semiconductor device.

Portable electronics devices, such as cellular telephones, personal digital assistants (PDAs), digital video cameras (DVCs), and digital still cameras (DSCs), are increasingly becoming more sophisticated. The market demands compact and lightweight products. Highly integrated system large scale integration (LSI) technology is one solution for satisfying such market demand.

An example of a module for realizing a highly integrated system LSI is a high-frequency bipolar transistor. A heterojunction bipolar transistor having a base layer fabricated with a silicon-germanium (SiGe) alloy is an example enabling a high-frequency bipolar transistor to exhibit higher performance.

Japanese Laid-Open Patent Publication No. 2002-16077 describes a first prior art example of a method for manufacturing a heterojunction bipolar transistor including a SiGe alloy base layer. Referring to FIG. 37, a p-type silicon substrate 110 has an embedded sub-collector layer 101. An oxide film, or element isolation film 103, is formed on the p-type silicon substrate 110 through local oxidation of silicon (LOCOS) to separate devices. This defines an active region 102a surrounded by the element isolation film 103. An epitaxially grown SiGe alloy layer 107, which functions as a base layer, is formed on the element isolation film 103 and the active region 102a. A base electrode 141, which is made of an aluminum-silicon (AlSi) alloy, is formed on a portion of the element isolation film 103 that is leftward from the active region 102a with a titanium silicide film 113 located therebetween. A collector opening, which extends to the embedded sub-collector layer 101, is formed in a portion of the element isolation film 103 that is rightward from the active region 102a. In the collector opening, a collector compensation region 105, a polycrystalline silicon film 111, and a titanium silicide film 113 are formed. A collector electrode 131, which is made of an AlSi alloy, is formed on the titanium silicide film 113. A silicon epitaxial layer 102, which is doped with phosphorous, is formed in the active region 102a excluding the element isolation film 103. The silicon epitaxial layer 102 functions as a collector layer. On the epitaxial layer 102, the SiGe alloy layer 107 (base layer), a silicon epitaxial film (emitter layer 108), a polycrystalline silicon film 111, and a titanium silicide film 113 are formed. An emitter electrode 121, which is made of an AlSi alloy, is formed on the titanium silicide film 113. A side wall 115, which is an insulative film, is formed around the emitter layer 108 and the polycrystalline silicon film 111.

In the prior art configuration, to form a high performance bipolar transistor having a high cutoff frequency, the impurity concentration of the collector layer (active region 102a) must be high so that a collector-base depletion layer is not modulated to a high current operation region. However, when forming the collector layer with a high impurity concentration in the prior art configuration, the impurity concentration becomes high not only at the portion of the collector layer located immediately below the emitter layer 108 (silicon epitaxial film) but in the entire collector layer. As a result, the collector-base junction capacitance increases. This increases the parasitic capacitance.

Japanese Laid-Open Patent Publication No. 4-179235 describes a second prior art example of a method for manufacturing a bipolar transistor (refer to FIGS. 38 and 39). As shown in FIG. 38, an n⁺-type collector embedment layer 201 is formed on a p⁻-type silicon substrate (not shown). An n⁻-type layer 202 (epitaxial layer), which functions as a collector layer, is formed on the n⁺-type collector embedment layer 201. The n⁻-type layer 202 is etched and removed excluding portions required for use as the collector layer and a collector extraction layer. An element isolation region includes a trench, of which surface is covered by an oxide film 203, and a polycrystalline silicon film 204, which is embedded in the trench. After the formation of the collector and element isolation region, a flat oxide film 205 (embedment oxide film) is formed on the surface of the substrate. A p-type SiGe layer 206 (SiGe alloy layer), which functions as an internal base layer, is formed on the oxide film 205. Then, an n-type silicon layer 207, which functions as an emitter layer, and an n⁺-type silicon layer 208, which functions as an emitter-contact layer (emitter electrode), are epitaxially grown on the SiGe layer 206. While using an oxide film 209 as a mask, the n⁺-type silicon layer 208 and the n-type silicon layer 207 are etched and removed excluding portions required to form the emitter. The outer side of the region functioning as the internal base layer in the residual p-type SiGe layer 206 is etched for a predetermined depth using an oxide film (side wall film 210) and the oxide film 209 as masks. This portion then undergoes selective epitaxial growth to form a p⁺-type SiGe layer 211, which functions as an external base layer.

As shown in FIG. 39, in the SiGe base heterojunction bipolar transistor configuration of the prior art, the n-type silicon layer 207 (emitter layer) includes a relatively narrow upper surface 50 and a relatively wide lower surface. The upper surface 50 is located at a position that is higher than a lower surface 60 of the side wall film 210. The width of the lower surface of the emitter layer is about the same as the outer dimension (Wₑ₂) of the side wall film 210. Accordingly, the width Wₑ₂ of the emitter-base junction, which is located below the n-type silicon layer 207, is much greater than the width Wₑ₁ of the n⁺-type silicon layer 208 (emitter electrode).

To manufacture a semiconductor device (SiGe base heterojunction bipolar transistor) having higher capacity performance, the n⁺-type silicon layer 208 (emitter electrode) must further be processed in a miniaturized manner to decrease the width Wₑ₁ and further decrease the width Wₑ₂ of the emitter layer. However, this would result in the need of a highly accurate exposure apparatus and thus increase manufacturing costs.

### SUMMARY OF THE INVENTION

It is an object of the present invention to provide a high performance semiconductor device including a collector layer with a high impurity concentration. A further object of the present invention is to provide a high performance semiconductor device having a narrowed emitter layer.

One aspect of the present invention is a semiconductor device including a semiconductor substrate. An element isolation film is arranged on the semiconductor substrate. An active region surrounded by the element isolation film functions as a collector layer. A conductive layer arranged on the active region functions as a base layer. An emitter layer is arranged on a portion of the conductive layer. An emitter electrode is arranged on the emitter layer and has a side surface. A first film covers the side surface of the emitter electrode. A first impurity region adjacent to the conductive layer functions as an external base layer. A second impurity region is formed in part of a surface of the active region and extends between the element isolation film and a portion of the conductive layer located below the emitter electrode. The active region contains first conductive type impurities. The first impurity region contains second conductive type impurities of a conductive type opposite to the first conductive type impurities. The second impurity region is of a conductive type that is the same as the first impurity region and has conductivity that is less than that of the first impurity region.

Another aspect of the present invention is a semiconductor device including a semiconductor substrate. An element isolation film is arranged on the semiconductor substrate. An active region surrounded by the element isolation film functions as a collector layer. A conductive layer arranged on the active region functions as a base layer. An emitter layer is arranged on a portion of the conductive layer. An emitter electrode is arranged on the emitter layer and has a side surface. A first film covers the side surface of the emitter electrode. A first impurity region adjacent to the conductive layer functions as an external base layer. A second impurity region is formed in part of a surface of the active region and extends between the element isolation film and a portion of the conductive layer located below the emitter electrode. The active region contains first conductive type impurities. The first impurity region contains second conductive type impurities of a conductive type opposite to the first conductive type impurities. The second impurity region is of a conductive type that is the same as the active region and has conductivity that is less than that of the active region.

A further aspect of the present invention is a semiconductor device including a semiconductor substrate. An element isolation film is arranged on the semiconductor substrate. An active region surrounded by the element isolation film functions as a collector layer. A conductive layer arranged on the active region functions as a base layer. An emitter layer is arranged on a portion of the conductive layer. An emitter electrode is arranged on the emitter layer and has a side surface. A first film covers the side surface of the emitter electrode. A first impurity region, adjacent to the conductive layer, functions as an external base layer. A second impurity region is formed in part of a surface of the active region and extends between the element isolation film and a portion of the conductive layer located below the emitter electrode. The active region contains first conductive type impurities. The conductive layer includes third conductive type impurities of a conductive type opposite to the first conductive type impurities. The second impurity region is of a conductive type that is the same as the conductive layer and has conductivity that is less than that of the conductive layer.

Another aspect of the present invention is a semiconductor device including a semiconductor substrate. An element isolation film is arranged on the semiconductor substrate. An active region surrounded by the element isolation film functions as a collector layer. A conductive layer arranged on the active region functions as a base layer. An emitter layer is arranged on a portion of the conductive layer. An emitter electrode arranged on the emitter layer has a side surface. A first film covers the side surface of the emitter electrode. A first impurity region adjacent to the conductive layer functions as an external base layer. A second impurity region is formed in part of a surface of the active region and extends between the element isolation film and a portion of the conductive layer located below the emitter electrode. The active region contains first conductive type impurities. The conductive layer includes third conductive type impurities of a conductive type opposite to the first conductive type impurities. The second impurity region is of a conductive type that is the same as the conductive layer and has conductivity that is less than that of the conductive layer.

A further aspect of the preset invention is a semiconductor device including a semiconductor substrate. An element isolation film is arranged on the semiconductor substrate. An active region of a first conductive type surrounded by the element isolation film functions as a collector layer. An alloy layer of a second conductive type is arranged on the active region. An emitter layer of the first conductive type is arranged on the alloy layer. The alloy layer includes a first portion, arranged immediately below the emitter layer and functioning as a base layer, and a second portion, electrically connected to the base layer and functioning as an external base layer. A surface of the active region includes an impurity region, which includes impurities of the second conductive type, and a region, which is surrounded by the impurity region and which contacts a lower surface of the base layer and which is free from impurities of the second conductive type.

Another aspect of the present invention is a method for manufacturing a semiconductor device. The method includes preparing a semiconductor substrate and forming an active region of a first conductive type surrounded by an element isolation film on the semiconductor substrate, forming an alloy layer of a second conductive type on the element isolation film and the active region, forming an emitter electrode of a first conductive type on the alloy layer and above the active region, implanting second conductive type impurities from above the emitter electrode and the alloy layer to selectively form an impurity region containing the second conductive type impurities in a surface of the active region at a portion excluding a portion located below the emitter electrode, and diffusing first conductive type impurities included in the emitter electrode into a portion of the alloy layer to form an emitter layer.

A further aspect of the present invention is a semiconductor device including a semiconductor substrate. A collector layer is formed on the semiconductor substrate. A conductive layer is formed on the collector layer and functions as a base layer. A silicon film is arranged on the conductive layer and includes first impurities. The silicon film includes a first region and a second region excluding the first region. An emitter electrode has a side surface and is formed on the first region of the silicon film. A first film covers the side surface of the emitter electrode and has a lower surface. The first region of the silicon film contacts the emitter electrode and functions as an emitter layer. The first region includes a contact surface for contacting the emitter electrode. The contact surface is located farther from the semiconductor substrate than the lower surface of the first film. The second region of the silicon film is at least partially arranged between the conductive layer and the first film so as to contact both of the conductive layer and the first film. The first film is a laminated film including a silicon nitride film and a silicon oxide film. The silicon nitride film includes a portion arranged between the silicon oxide film and the silicon film.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a cross-sectional view of a semiconductor device according to a first embodiment of the present invention;

FIGS. 2 to 13 are cross-sectional views showing the procedures for manufacturing the semiconductor device of FIG. 1;

FIGS. 14a and 14b are graphs showing resistivities in the vicinity of a collector-external base junction when an impurity region in the semiconductor device of FIG. 1 are respectively p-type conductive and n-type conductive;

FIG. 15 is a graph showing the resistivity in the vicinity of a base-external base junction in the semiconductor device of FIG. 1;

FIG. 16 is a cross-sectional view of a semiconductor device according to a second embodiment of the present invention;

FIG. 17 is a cross-sectional view showing the thickness of a silicon oxide film in the semiconductor device of FIG. 16;

FIG. 18 is a cross-sectional view showing a semiconductor device according to a third embodiment of the present invention;

FIGS. 19 to 23 are cross-sectional views showing the procedures for manufacturing the semiconductor device of FIG. 18;

FIG. 24 is a cross-sectional view showing a semiconductor device according to a fourth embodiment of the present invention;

FIG. 25 is an enlarged partial view of the semiconductor device of FIG. 24;

FIGS. 26 to 35 are cross-sectional diagrams showing the procedures for manufacturing the semiconductor device of FIG. 24;

FIG. 36 is a cross-sectional view showing a semiconductor device according to a fifth embodiment of the present invention;

FIG. 37 is a cross-sectional diagram showing a first prior art example of the configuration of an SiGe base heterojunction bipolar transistor;

FIG. 38 is a cross-sectional diagram showing a second prior art example of the configuration of an SiGe base heterojunction bipolar transistor; and

FIG. 39 is an enlarged partial view of the transistor shown in FIG. 38.

### DETAILED DESCRIPTION OF THE PREFERRED EMBODIMENTS

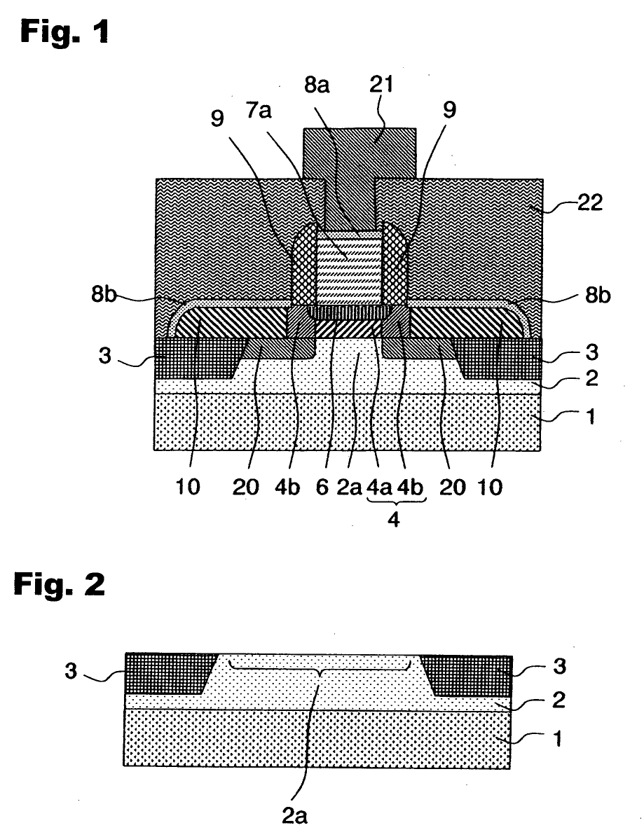

An SiGe base heterojunction bipolar transistor according to a first embodiment of the present invention will now be described. With reference to FIG. 1, an element isolation film 3 is formed above a p-type silicon substrate through shallow trench isolation. A collector layer 2, which includes an active region 2a surrounded by the element isolation film 3, is formed on the p-type silicon substrate 1. An SiGe alloy layer 4 (first alloy layer 4a and second alloy layer 4b), which functions as a base layer, is formed on the active region 2a. An n-type diffusion layer 6, which functions as an emitter layer, is formed on the first alloy layer 4a. The n-type diffusion layer 6 is part of the SiGe alloy layer 4, which includes n-type impurities diffused from a polycrystalline film 7a. The polycrystalline silicon film 7a and a silicide film 8a are formed on the n-type diffusion layer 6. A side wall film 9 (normally referred to as a side wall), which is an insulative film, is formed around sides of the polycrystalline silicon film 7a and silicide film 8a.

An impurity region 20 is formed in the surface of the active region 2a between the first alloy layer 4a, which is located under the polycrystalline silicon film 7a, and the element isolation film 3. The impurity region 20 is formed in a self-aligning manner by adding p-type impurities to the active region 2a using the silicon nitride film 11 and the element isolation film 3 as a mask. During the formation of the impurity region 20, the SiGe alloy layer located between the impurity region 20 and the side wall film 9 is formed as the second alloy layer 4b. A p⁺ diffusion layer 10, which functions as an external base layer, is formed adjacent to the second alloy layer 4b. The boundary between the p⁺ diffusion layer 10 and the second alloy layer 4b is located on the impurity region 20.

A silicide film 8b is formed on the surface of the p⁺ diffusion layer 10 to function as a low resistance layer of the external base layer. Then, an interlayer insulation film 22 is formed with a flattened upper surface. An electrode 21 connecting to the emitter layer (n-type diffusion layer 6) is formed so that the electrode 21 is connected to silicide film 8a formed on the polycrystalline silicon film 7a.

The p⁺ diffusion layer 10 is an example of a first impurity region. The impurity region 20 is an example of a second impurity region.

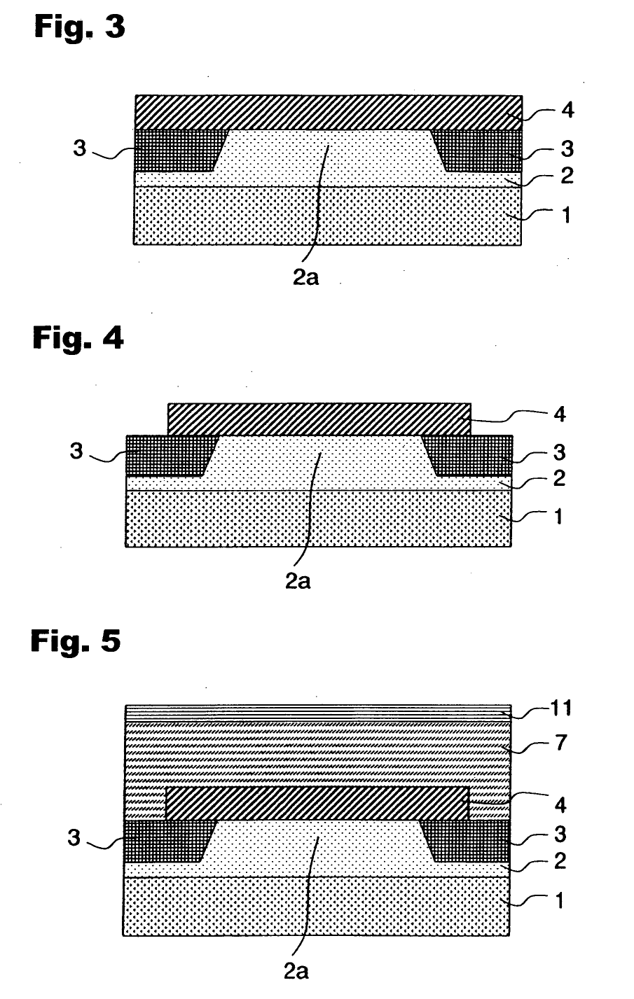

The procedures for manufacturing the semiconductor device of FIG. 1 will now be described with reference to FIGS. 2 to 13.

[Process 1: FIG. 2] The element isolation film 3 is formed on the p-type silicon substrate 1 by performing, for example, STI. Then, n-type impurities are ion-implanted and activated to form the active region 2a (collector layer 2). For example, phosphorous (P) is implanted with an accelerating energy of approximately 500 to 4000 keV to obtain a concentration of about 3×10¹³ cm⁻² to 3×10¹⁵ cm⁻². Then, heat treatment is performed at a temperature of about 1000° C. Further, a collector drawing diffusion layer is formed (not shown).

[Process 2: FIG. 3] Low pressure chemical vapor deposition (CVD) is performed to epitaxially grow the silicon-germanium (SiGe) alloy layer 4, in which boron (B) is doped at a concentration of approximately 1×10¹⁹ cm⁻³. The SiGe alloy layer 4 has a thickness of approximately 80 nm.

The Ge concentration in the SiGe alloy layer 4 may be uniform throughout the layer. Alternatively, the Ge concentration in the SiGe alloy layer 4 may have a gradient doping profile so that the Ge concentration gradually increases from the surface side (the side on which the emitter layer is subsequently formed) toward the collector layer 2. This would shorten the time electrons travel through the base and form a transistor that operates at high speeds. In such a case, it is preferred that the Ge concentration substantially be about 0% at the surface side and about 15% to 20% at the side contacting the active layer 2a (collector layer 2).

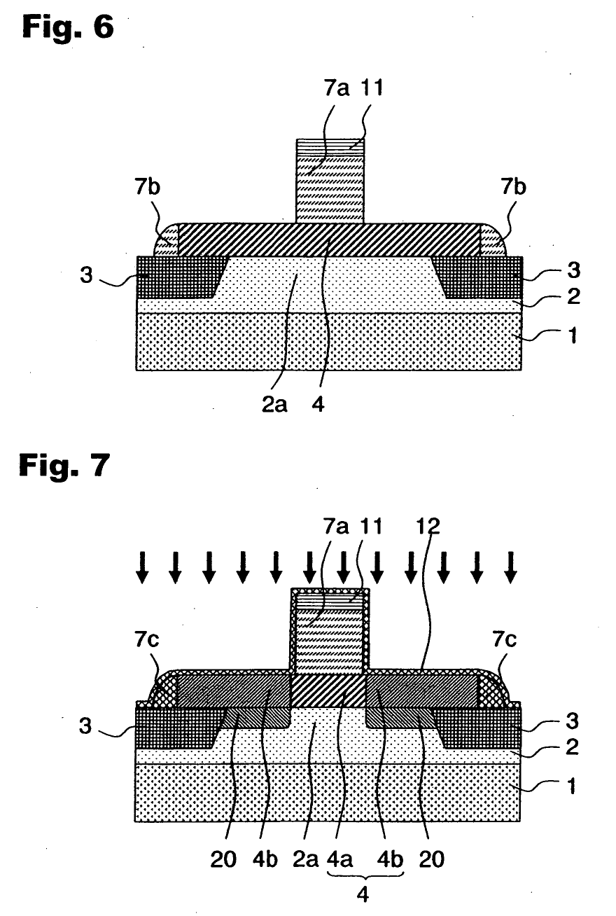

Prior to, subsequent to, or prior to and subsequent to the formation of the SiGe alloy layer 4, low pressure CVD may be performed to epitaxially grow a silicon film that does not include boron (B) or an SiGe alloy layer that does not include boron (B).

[Process 3: FIG. 4] Next, lithography is performed to form a resist pattern. Then, dry etching is performed using the resist pattern as a mask to remove unnecessary portions from the SiGe alloy layer 4.

[Process 4: FIG. 5] Low pressure CVD is performed to form a polycrystalline silicon film 7, which is doped with n-type impurities of approximately 1×10²⁰ cm⁻³ or more, and a silicon nitride film 11. Examples of the n-type impurities are arsenic (As) and phosphorus (P). The thickness of the polycrystalline silicon film 7 is approximately 200 nm. The thickness of the silicon nitride film 11 is approximately 100 nm.

[Process 5: FIG. 6] Lithography is performed to form a resist pattern. Then, dry etching is performed using the resist pattern as a mask to sequentially remove the silicon nitride film 11 and the polycrystalline silicon film 7. The polycrystalline silicon film 7 is processed to form the polycrystalline silicon film 7a, which functions as an emitter electrode, and the side wall film 7b, which surrounds the SiGe alloy layer 4.

[Process 6: FIG. 7] Low pressure CVD is performed to form a silicon oxide film 12. Then, while using the silicon nitride film 11 and the element isolation film 3 as a mask, boron (B) is ion-implanted and then activated by performing a heat treatment to form the impurity region 20 in the surface of the activation region 2a. The ion implantation is performed, for example, by implanting BF₂ at an amount of 1×10¹⁴ cm⁻² to 5×10¹⁵ cm⁻² with an accelerating energy of 50 keV to 100 keV.

The impurity region 20 is formed by adding to the conductive impurities (n-type impurity: P) included in the active region 2a opposite conductive impurities (p-type impurity: B). The SiGe alloy layer 4 excluding portions immediately under the polycrystalline silicon film 7a becomes the second alloy layer 4b. The side wall film 7b, which is formed by a polycrystalline silicon film, becomes a polycrystalline silicon film 7c that contains impurities. The SiGe alloy layer 4 immediately under the polycrystalline silicon film 7a (the SiGe alloy layer 4 to which the opposite conductive impurities are not added) is defined as the first alloy layer 4a.

The impurity region 20 is a mixed phase of two types of impurities having different conductive types. More specifically, the impurity region 20 is formed from phosphorous (P), which is the n-type impurity included in the active region 2a that is the basis of the impurity region 20, and boron (B), which is the p-type impurity implanted in the present process 6. The impurity concentration of the impurity region 20 is extremely low and close to a true semiconductor that does not include impurities.

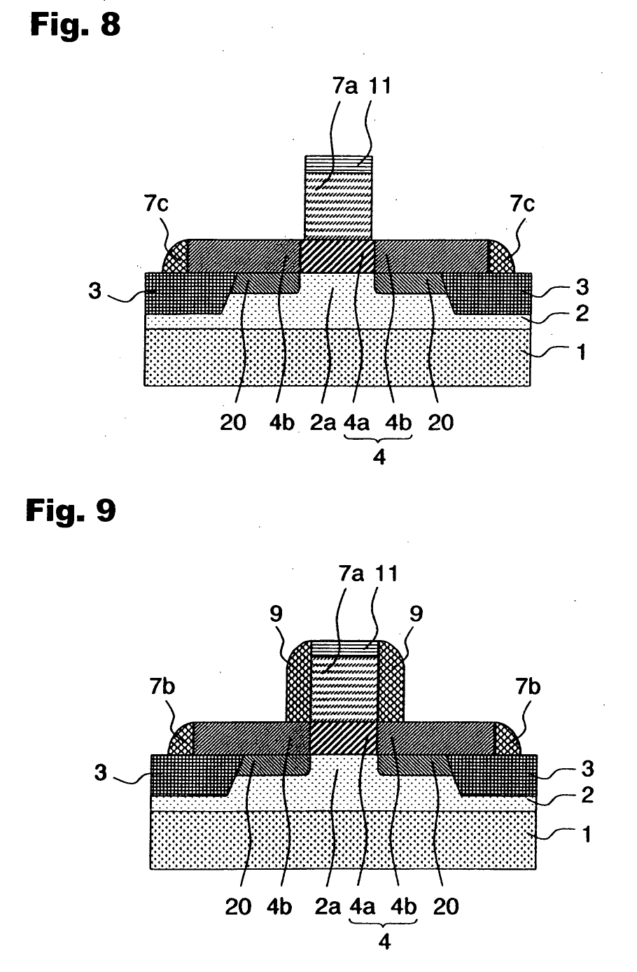

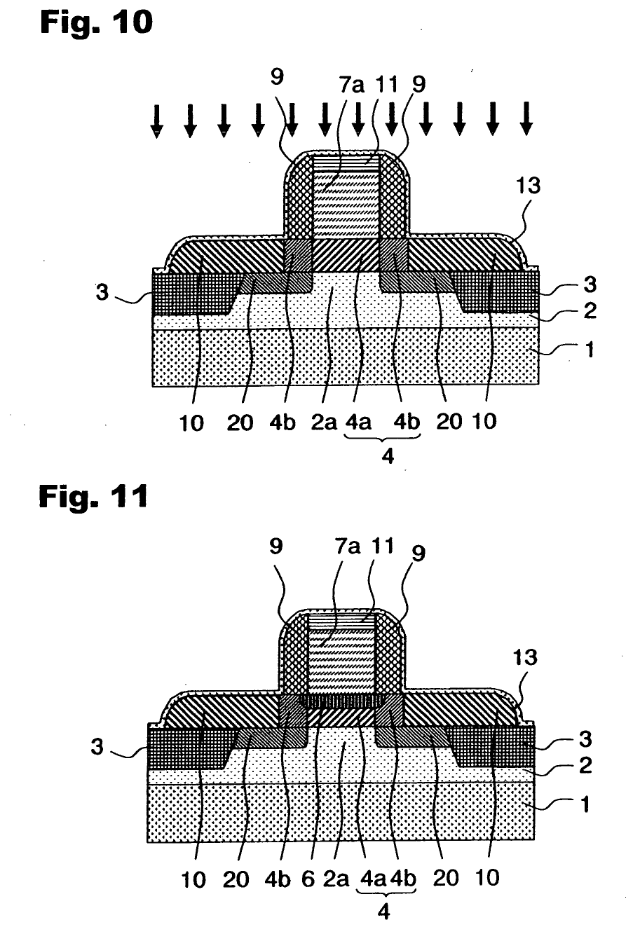

The above technique enables the area of the impurity region 20 that can be formed on the collector layer (active region) to be maximized. Further, the active region 2a is formed only directly below the emitter electrode (polycrystalline silicon film 7a). Thus, a parasitic transistor is not formed, and the basic transistor characteristics are improved. Further, even if the resist pattern is misaligned in process 5, the collector layer immediately below the emitter electrode may be formed stably and in a repetitive manner.

[Process 7: FIG. 8] The silicon oxide film 12 is removed with dilute fluoric acid.

[Process 8: FIG. 9] CVD is performed to form a silicon oxide film. Then, dry etching is performed to carry out complete surface etch back and form the side wall film 9, which is referred to as a side wall, and formed around the silicon nitride film 11 and the polycrystalline silicon film 7a. The silicon oxide film is formed by, for example, heating a mixed gas of tetraethoxysilane (TEOS) and oxygen (O₂) under a temperature of 720° C. The thickness of the silicon oxide film is approximately 200 nm.

[Process 9: FIG. 10] Low pressure CVD is performed to form a silicon oxide film 13. While using the silicon nitride film 11, the side wall film 9, and the element isolation film 3 as a mask, boron (B) is ion-implanted and then activated by performing a heat treatment to form the p⁺ diffusion layer 10, which functions as an external base layer. The ion implantation is performed by implanting BF₂ at an amount of 1×10¹⁴ cm⁻² to 5×10¹⁵ cm⁻² with an accelerating energy of 1 keV to 30 keV.

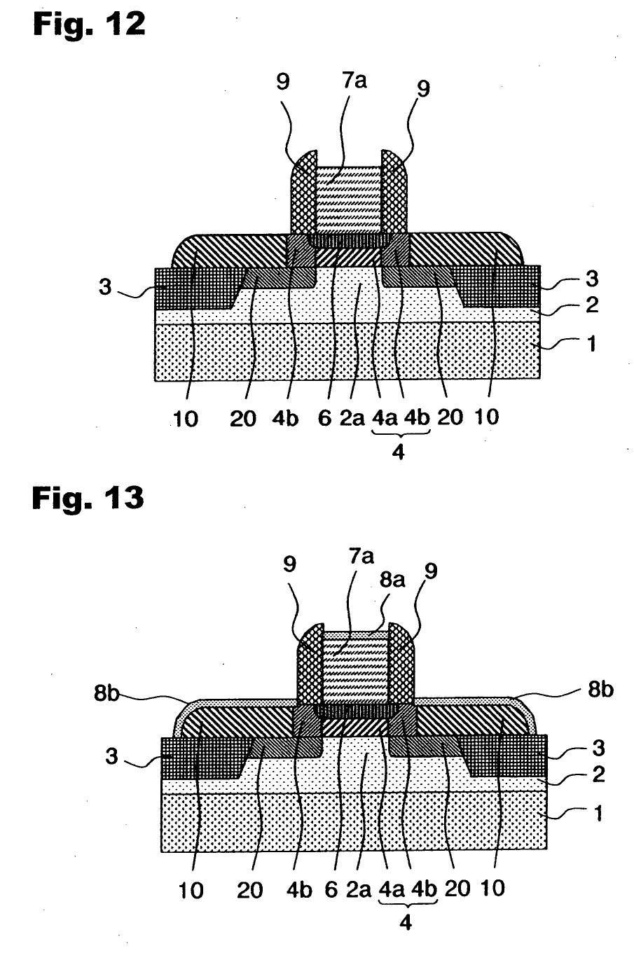

As a result, the p⁺ diffusion layer 10 is formed at a location shifted from the impurity region 20, which is formed by using the emitter electrode (polycrystalline silicon film 7a) as a mask, by an amount corresponding to the thickness (thickness in the horizontal direction) of the side wall film 9. As a result, the junction capacitance between the p⁺ diffusion layer and the collector layer is produced only at the junction with the impurity region 20, of which capacitance is smaller than that at the junction with the active region 2a. Thus, in comparison to when the junction of the p⁺ diffusion layer 10 and the second alloy layer 4b is located on the active region 2a (when the junction with the active region 2a exists on the p⁺ diffusion layer 10), the junction capacitance between the collector and the external base layer may be reduced. Further, even if the resist pattern is misaligned in process 5, the p⁺ diffusion layer 10 may be formed stably and in a repetitive manner at a location shifted from the impurity region 20 by an amount corresponding to the thickness (thickness in the horizontal direction) of the side wall film 9. The concentration of boron (B) in each layer increases in the order of the first alloy layer 4a, the second alloy layer 4b, and the p⁺ diffusion layer 10.

[Process 10: FIG. 11] Heat treatment is performed to diffuse the n-type impurities of the polycrystalline silicon film 7a into the SiGe alloy layer 4 (4a, 4b) and form the n-type diffusion layer 6. As a result, the emitter-base junction is formed in the SiGe alloy layer 4. The heat treatment is performed with a rapid thermal annealing (RTA) apparatus under a temperature of about 1050° C. for a period of 5 to 30 seconds. The heat treatment of process 10 can be controlled so that the boundary between the p⁺ diffusion layer 10 and the second alloy layer 4b reaches beneath the side wall film 9.

[Process 11: FIG. 12] Subsequent to the heat treatment, the silicon oxide film 13 and the silicon nitride film 11 on the emitter electrode are removed with dilute fluoric acid and phosphoric acid. Although not shown in the drawings, the silicon oxide film 13 and the silicon nitride film 11 on the base electrode and the collector electrode are also simultaneously removed.

[Process 12: FIG. 13] A cobalt (Co) layer is formed on the surface of the polycrystalline silicon film 7a and the surface of the p⁺ diffusion layer 10, which functions as the external base layer. The cobalt layer is heat treated to form cobalt silicide films (silicide films 8a and 8b). The sheet resistance of the silicide films 8a and 8b is approximately 5 Ω/square. The sheet resistance of the silicide films 8a and 8b is much smaller than the sheet resistance of the prior art p⁺ diffusion layer 19 that is approximately 100 Ω/square. Thus, the silicide films 8a and 8b lower the parasitic resistance produced between the internal base layer (first alloy layer 4a and second alloy layer 4b) and the base electrode (not shown), which is connected to the external base layer.

In the silicide processing, titanium (Ti) may be used in lieu of cobalt to form a titanium silicide film. This would have the same effects.

[Process 13: FIG. 1] The interlayer insulation film 22, such as a plasma TEOS film, is deposited on the surface of a semiconductor substrate. Further, a contact hole is formed in a collector electrode (not shown), base electrode (not shown), and emitter electrode of an NPN transistor. Then, a conductive layer (electrode 21) is formed. The electrode 21 includes a barrier metal layer, made of titanium or the like, and a conductive layer, made of aluminum or aluminum alloy, is formed. This completes the manufacturing of a bipolar transistor having an NPN transistor.

The first embodiment has the advantages described below.

In the SiGe base heterojunction bipolar transistor, the impurity region 20 is formed in the surface of the active region 2a excluding the portion located immediately below the emitter layer (n-type diffusion layer 6). The impurity region 20 includes p-type impurities, the conductive type of which is opposite to the conductive type of the n-type impurities included in the active region 2a. The conductive type of the impurity region 20 determined in accordance with the amount of n-type impurities included in the active region 2a and the implanted amount of the p-type impurities. Thus, the conductive type of the impurity region 20 may be any one of n-type or p-type. The impurity region 20 that includes impurities of different conductive types has a property close to that of a true semiconductor. Accordingly, the conductivity of the impurity region 20 is sufficiently lower than that of the active region 2a (collector layer) and the p⁺ diffusion layer 10 (external base layer).

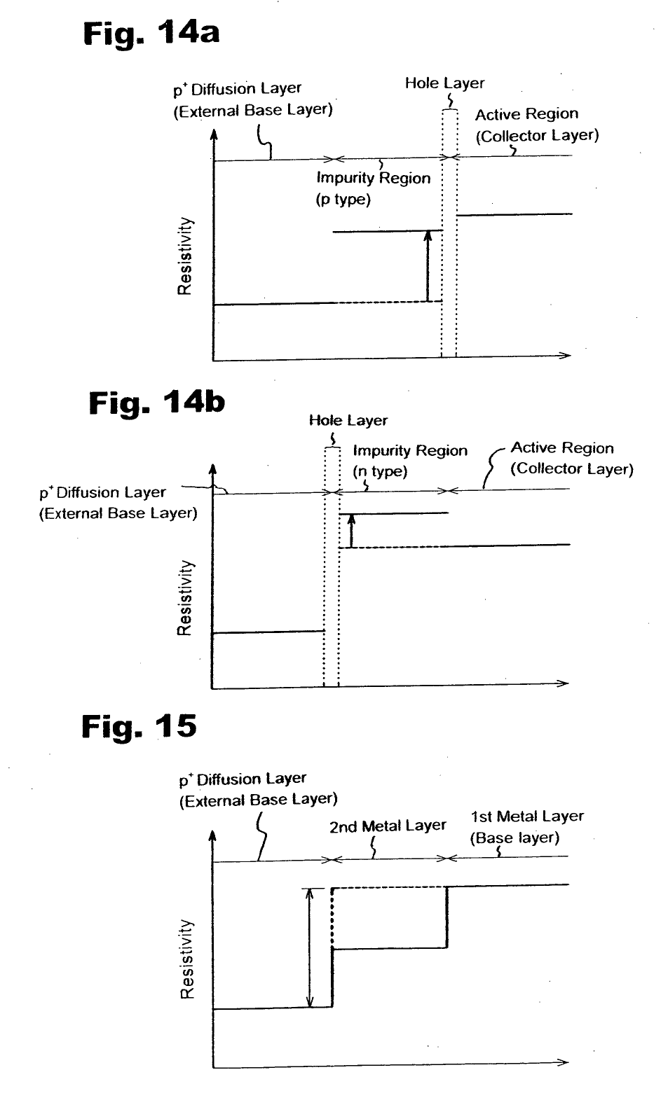

The following is an observation of the junction capacitance between the collector and external base. A depletion layer is formed in a pn junction interface between the collector and the external base. The dielectric constant decreases as the resistance of the layer sandwiching the depletion layer increases. This decreases the capacitance of the depletion layer. When the impurity region 20 is p-type conductive, a pn junction is formed between the active region 2a and the impurity region 20. FIG. 14a shows the resistivity near a pn junction. The conductivity of the impurity region 20 is sufficiently lower than that of the p⁺ diffusion layer 10. Thus, the junction capacitance is lower in comparison to when the active region 2a directly contacts the p⁺ diffusion layer 10 without the impurity region 20. If the impurity region 20 is n-type conductive, a pn junction is formed between the impurity region 20 and the p⁺ diffusion layer 10 (and part of the second alloy layer 4b). FIG. 14b shows the resistivity near a pn junction. The substantial impurity of the impurity region 20 is lower than that of the active region 2a due to additional implantation of p-type impurities. This decreases the conductivity of the impurity region 20. Thus, the junction capacitance is lower in comparison to when the active region 2a directly contacts the p⁺ diffusion layer 10 and the impurity region 20.

In the first embodiment, even if the collector concentration, or the n-type impurity concentration of the active region 2a, is increased, the collector concentration may effectively be decreased by using the active region 2a, excluding portions immediately below the emitter layer (n-type diffusion layer 6) on which the substantial npn junction of the transistor is formed, as the impurity region 20. The high concentration of the collector increases the cut off frequency of the bipolar transistor. However, the junction capacitance between the collector and the external base is prevented from increasing. Accordingly, a high performance bipolar transistor (semiconductor device) is obtained through the first embodiment.

The impurity region 20 is arranged on the surface of the active region between the element isolation film and the conductive layer located under the emitter electrode. This locally forms the active region (collector layer) under only the emitter layer. In this configuration, a parasitic transistor is not formed, and the basic transistor characteristics are improved.

Generally, in an SiGe base heterojunction bipolar transistor, base current flows from the external base layer to the base layer. The difference in resistivity between the external base layer and the base layer is more than single digits. At the boundary between layers where the resistivity differs greatly, the current characteristics deteriorate greatly. Thus the transistor characteristics may deteriorate if the external base layer and the base layer are directly connected to each other. In the bipolar transistor of the first embodiment, the second alloy layer 4b is arranged between the external base layer (p⁺ diffusion layer 10) and the base layer (first alloy layer 4a). The concentration of the p-type impurities (B) increases in the order of the base layer, the second alloy layer 4b, and the external base layer. More specifically, with reference to FIG. 15 showing the change in resistivity in the vicinity of the boundary between the base layer and the external base layer, the conductivity of the second alloy layer 4b is greater than that at the base layer and less than that of the external base layer (resistivity: external base layer<second alloy layer<base layer). In this manner, there are a plurality of layer connections between the base layer and the external base layer. Thus, change in the resistivity at each layer connection is sufficiently lower in comparison to when the base layer and the external base layer are directly connected to each other. This bonds the external base layer and the base layer that have a layer resistivity difference in an ohmic linearity without forming a portion that drastically changes the resistivity. Thus, in the bipolar transistor of the first embodiment, the deterioration of the current characteristics is suppressed in a preferable manner when the base current flows.

A semiconductor device according to a second embodiment of the present invention will now be discussed.

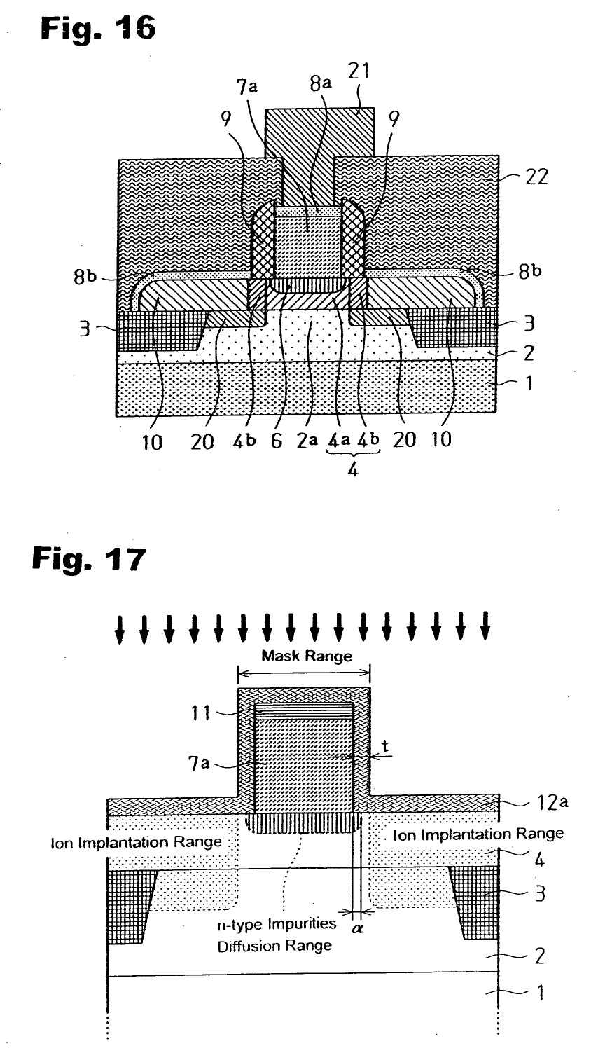

Parasitic capacitance that deteriorates the characteristics of a bipolar transistor is included in junction capacitance between the emitter and the base. In the semiconductor device of the second embodiment, the junction capacitance between the emitter and the base is reduced. Referring to FIG. 16, the SiGe base heterojunction bipolar transistor of the second embodiment has the same configuration as that of the first embodiment except in the portion connecting the emitter and base. The base layer of the bipolar transistor is formed by a first alloy layer 4a and a second alloy layer 4b. The first alloy layer 4a, which is located immediately below the emitter layer, has a high resistivity and a low conductivity. The second alloy layer 4b, which is located beside the first alloy layer 4a, has a low resistivity and a high conductivity. An n-type impurity diffusion layer 6 includes a high concentration of n-type impurities and functions as an emitter layer. The conductivity of the first alloy layer 4a is lower than that of the second alloy layer 4b. The n-type diffusion layer 6 contacts the first alloy layer 4a, which has a low conductivity, and does not contact the second alloy layer 4b. The junction capacitance increases when the conductivity between two layers sandwiching a depletion layer formed in the pn junction increases. However, in the semiconductor device of the second embodiment, the n-type diffusion layer 6 (emitter layer) does not directly contact the second alloy layer 4b, which has high conductivity. This drastically reduces the junction capacitance between the emitter and the base. Further, in the same manner as in the first embodiment, the junction capacitance between the emitter and the external base is reduced.

The procedures for manufacturing the semiconductor device of the second embodiment will now be described focusing on differences from the first embodiment.

In the second embodiment, processes 1 to 5 of the first embodiment are performed. Then, in process 6, low pressure CVD is performed to form a silicon oxide film 12a having a predetermined thickness t.

The thickness of the silicon oxide film 12a will now be discussed. An ion implantation technique is used to form an impurity region 20 by implanting boron (B) in the active region 2a. Boron (B) is also implanted in the SiGe alloy layer 4, which is located immediately above the impurity region 20 (refer to FIG. 17). The silicon nitride film 11 and the silicon oxide film 12a function as a mask. Thus, boron is not implanted below the silicon nitride film 11 and the silicon oxide film 12a. Accordingly, the SiGe alloy layer 4 includes the first alloy layer 4a, of which impurity concentration changes when ions are implanted, and the second alloy layer 4b, of which impurity concentration increases when ion is implanted.

In process 10 of the second embodiment, heat treatment is performed to diffuse the impurities of the polycrystalline silicon film 7a in the SiGe alloy layer 4. This forms the n-type diffusion layer 6, which functions as an emitter layer in which n-type impurities are diffused. The n-type impurities of the polycrystalline silicon film 7a are diffused not only in the vertical direction towards the semiconductor substrate 1 but also in a horizontal direction parallel to the semiconductor substrate 1. The n-type impurities are diffused in the SiGe alloy layer 4 within a diffusion range, which is extended in the horizontal direction from the side surface of the polycrystalline silicon film 7a by length α (refer to FIG. 17). In process 2 of the second embodiment, the silicon oxide film 12a is formed so that the thickness t is sufficiently greater than the extended length α. The thickness t of the silicon oxide film 12a is, for example, 30 to 50 nm.

The silicon oxide film 12a, which has the predetermined thickness t, causes the n-type impurities of the polycrystalline silicon film 7a to be diffused only in the first alloy layer 4a. Thus, the n-type impurities do not reach the second alloy layer 4b. The n-type diffusion layer 6 (emitter layer) formed after process 10 does not directly contact the second alloy layer 4b. This reduces the junction capacitance between the emitter and the base.

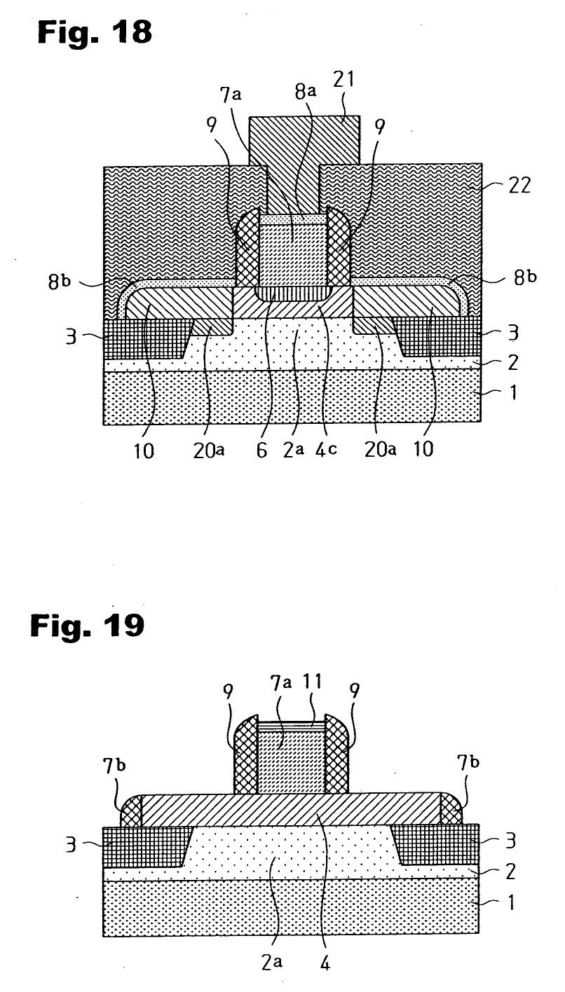

A semiconductor device according to a third embodiment of the present invention will now be described with reference to FIGS. 18 to 23.

The junction capacitance between the collector and the external base significantly and the parasitic resistance between the base and the external base influence the transistor characteristics. Therefore, in the third embodiment, among the two factors that lower the transistor characteristics, the junction capacitance between the collector and the external base is reduced to improve the transistor characteristics while reducing the number of procedures for manufacturing the semiconductor device and reducing manufacturing costs. More specifically, in the third embodiment, the second alloy layer 4b (refer to FIGS. 1 and 16) is eliminated, and an alloy layer 4c solely functions as a base layer as shown in FIG. 18. The alloy layer 4c is located immediately below the polycrystalline silicon film 7a and the insulative side wall film 9. The alloy layer 4c has a lower surface contacting the active region 2a. The side surface of the alloy layer 4c directly contacts the p⁺ diffusion layer 10, which functions as an external base layer. The impurity region 20a, to which p-type impurities are added, are formed in an outer portion of the surface of the active region 2a where portions immediately below the alloy layer 4c are excluded.

The procedures for manufacturing the semiconductor device of the third embodiment will now be discussed.

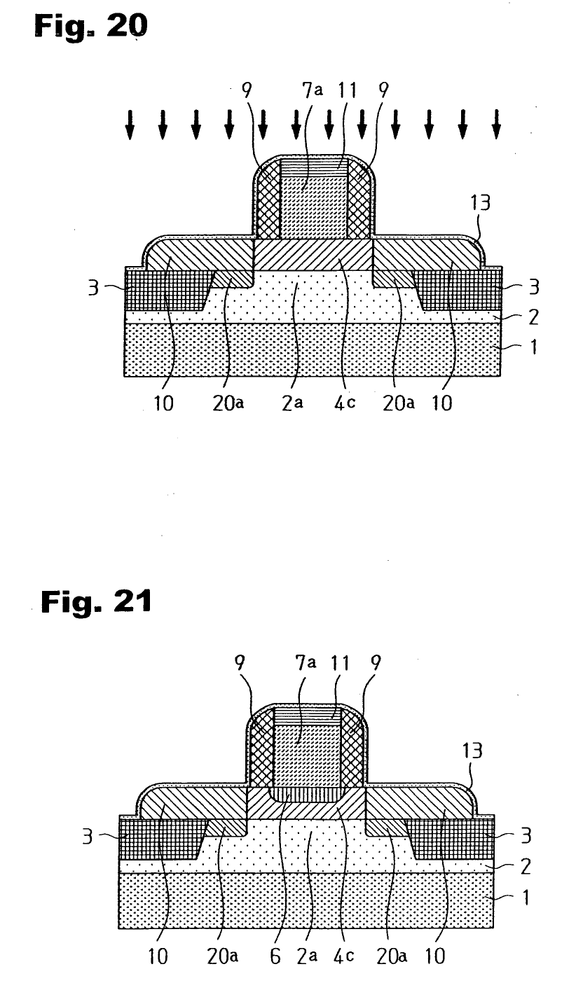

In the third embodiment, processes 1 to 5 of the first embodiment are performed to form the active region 2a on the SiGe alloy layer 4, form the polycrystalline silicon film 7a on the SiGe alloy layer 4, and form the silicon nitride film 11 on the polycrystalline silicon film 7a. Thereafter, processes 6A to 10A are performed.

[Process 6A: FIG. 19] CVD is performed to form a silicon oxide film on the p silicon substrate 1 on which the polycrystalline silicon film 7a and the silicon nitride film 11 are formed. Then, dry etching is performed to carry out complete surface etch back and form the side wall film 9 (side wall), which is the silicon oxide film, around the silicon nitride film 11 and the polycrystalline silicon film 7a. Process 6A corresponds to process 8 of the first embodiment. The silicon oxide film is formed by, for example, heating a mixed gas of tetraethoxysilane (TEOS) and oxygen (O₂) under a temperature of 720° C. The thickness of the silicon oxide film is approximately 200 nm. In the third embodiment, the side wall film 9 is formed before the formation of the impurity region 20.

[Process 7A: FIG. 20] Low pressure CVD is performed to form a silicon oxide film 13. Then, while using the silicon nitride film 11, the side wall film 9, and the element isolation film 3 as a mask, boron (B) is ion-implanted and then activated by performing a heat treatment to form the p⁺ diffusion layer 10. Process 7A corresponds to process 9 of the first embodiment but differs in the ion implantation conduction. The ion implantation is performed, for example, by implanting BF₂ at a concentration of 1×10¹⁴ cm⁻² to 5×10¹⁵ cm⁻² with an accelerating energy of 50 keV to 70 keV. The accelerating energy of process 7A in the third embodiment is greater than that in process 9 of the first embodiment. Boron (B) reaches the portion of the active region 2a located immediately under the SiGe alloy layer 4. This forms the impurity region 20a to which p-type impurities are added in the active region 2a. The change in the ion implantation condition for forming the p⁺ diffusion layer 10 forms the impurity region 20a that reduces the junction capacitance between the collector and the external base without increasing the number of processes.

Boron is not added to the portion of the SiGe alloy layer 4 located immediately below the silicon nitride film 11 and the side wall film 9, which function as a mask. The impurity concentration of the SiGe alloy layer 4 in this portion is not changed. Thus, the ion implantation divides the SiGe alloy layer 4 into the alloy layer 4c, of which impurity concentration is low, and the p⁺ diffusion layer 10, of which impurity region is high.

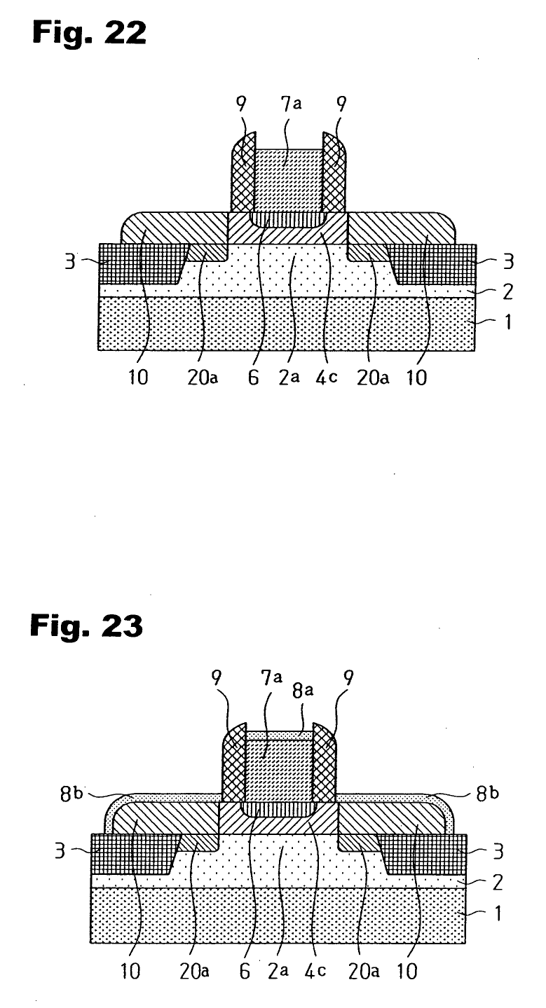

The use of the silicon nitride film 11, the side wall film 9, and the element isolation film 3 as a mask forms the impurity region 20a and the p⁺ diffusion layer 10 in a self-aligning manner. Thus, even if misalignment of the resist pattern occurs, the collector layer is locally formed immediately below the emitter electrode.

[Process 8A: FIG. 21] Heat treatment is performed to diffuse the n-type impurities of the polycrystalline silicon film 7a into the SiGe alloy layer 4 and form the n-type diffusion layer 6. As a result, the emitter-base junction is formed in the SiGe alloy layer 4. The heat treatment is performed with an RTA apparatus under a temperature of about 1050° C. for a period of 5 to 30 seconds. Process 8A corresponds to process 10 of the first embodiment.

[Process 9A: FIG. 22] Subsequent to the heat treatment, the silicon oxide film 13 and the silicon nitride film 11 on the emitter electrode are removed with dilute fluoric acid and phosphoric acid. Although not shown in the drawings, the silicon oxide film and the silicon nitride film on the base electrode and the collector electrode are also simultaneously removed. Process 9A corresponds to process 11 of the first embodiment.

[Process 10A: FIG. 23] A cobalt (Co) layer is formed on the surface of the polycrystalline silicon film 7a and the surface of the p⁺ diffusion layer 10. The cobalt layer is heat treated to form cobalt silicide films (silicide films 8a and 8b). Process 10A corresponds to process 12 of the first embodiment.

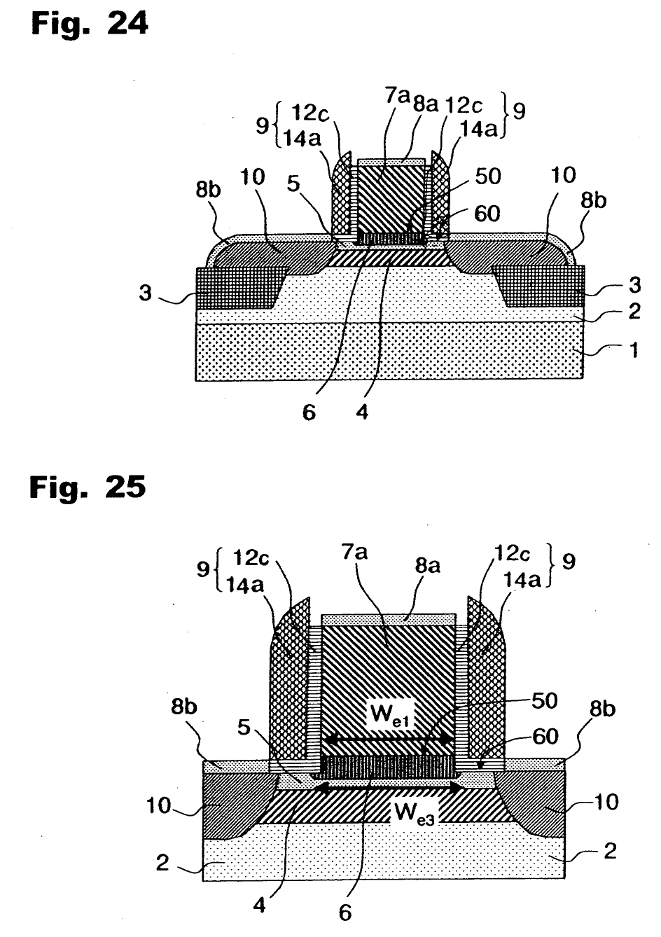

A semiconductor device according to a fourth embodiment of the present invention will now be discussed. The semiconductor device shown in FIG. 24 is an SiGe base heterojunction bipolar transistor.

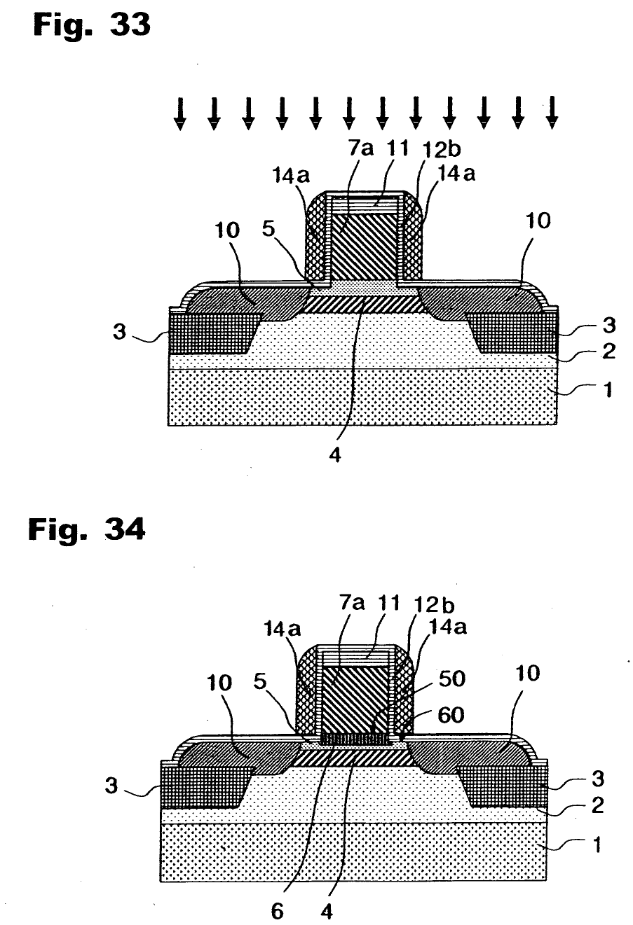

An epitaxial layer 2, which functions as a collector layer, is formed on the silicon substrate 1. Shallow trench isolation (STI) is performed to form the element isolation film 3 in part of the epitaxial layer 2. The SiGe alloy layer 4, which functions as a base region, is formed on the SiGe alloy layer 4. Further, n-type impurities are diffused into part of the silicon film 5 to form the n-type diffusion layer 6, which functions as an emitter layer. More specifically, as shown in FIG. 33, the silicon film 5 has a cross-section that has the shape of an upside down T. The n-type diffusion layer 6 is formed by diffusing n-type impurities in the projecting upper portion of the silicon film 5.

The polycrystalline silicon film 7a is formed on the n-type diffusion layer 6. The silicide film 8a is formed on the polycrystalline silicon film 7a. The insulative side wall film 9 (side wall) covers the n-type diffusion layer 6, the polycrystalline silicon film 7a, and the side surfaces of the silicide film 8a. The side wall film 9 is a laminated film of a silicon nitride film 12c and the silicon oxide film 14a.

A contact surface 50 between the n-type diffusion layer 6 and the polycrystalline silicon film 7a, that is, the bottom surface of the polycrystalline silicon film 7a is located above the lower surface 60 of the side wall film 9. Part of the silicon nitride film 12c is arranged between the silicon oxide film 14a and the silicon film 5. Another part of the silicon nitride film 12c is arranged between the silicon oxide film 14a and the n-type diffusion layer 6. The silicon film 5 has a peripheral portion arranged between the side wall film 9 and the SiGe alloy layer 4 so as to contact the lower surface 60 of the side wall film 9 and the upper surface of the SiGe alloy layer 4. The p⁺ diffusion layer 10 and the silicide film 8b, which are connected to the base region, are formed around the silicon film 5.

The silicon film 5 is an example of a second region. The n-type diffusion layer 6 is an example of a first region.

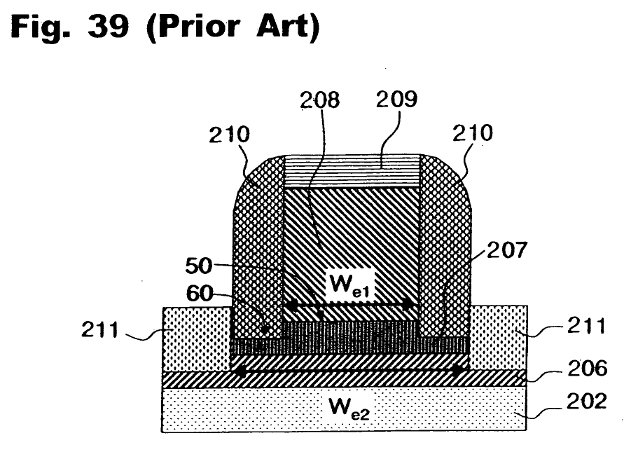

Referring to FIG. 39, in the semiconductor device of the prior art, the width of the emitter-base junction is Wₑ₂. Comparatively, in the semiconductor device of the fourth embodiment, the silicon film 5, which has the same dimensions as in the prior art, includes a first region (n-type diffusion layer 6) and a second region (region excluding the n-type diffusion layer 6). The second region includes a lower portion, which is located below the first region, and a peripheral portion, which surrounds the periphery of the first region. The first region 6 in the silicon film 5, which functions as an emitter layer, forms an emitter-base junction below the emitter layer. More specifically, in the semiconductor device of this embodiment, the width of the emitter-base junction is Wₑ₃, which is less than the wide of the interface between the silicon film 5 and the SiGe alloy layer 4 (width Wₑ₂ in FIG. 39). The width of the emitter layer, or the width Wₑ₃ may be adjusted to be the same as the width Wₑ₁ by controlling the diffusion of n-type impurities into the silicon film 5. As a result, the width Wₑ₃ may be decreased without employing a high accuracy exposure apparatus. When the width Wₑ₃ of the emitter layer is smaller than the width Wₑ₂ of the interface between the silicon film 5 and the SiGe alloy layer 4, the same current density may be obtained with less current. Accordingly, in the fourth embodiment, a transistor having low power consumption is formed, and a high performance semiconductor device is obtained.

In the fourth embodiment, at least part of the silicon film 5 is located between the SiGe alloy layer 4 and the side wall film 9 in a manner contacting the SiGe alloy layer 4 and the side wall film 9. The part excluding the part of the silicon film 5 is located between the SiGe alloy layer 4 and the side wall film 9 is related with the emitter-base junction. In the prior art configuration, the part corresponding to the silicon film 5 also functions as an emitter layer. The area of the emitter-base junction in the configuration of the fourth embodiment is less than in comparison to that of the prior art configuration. Accordingly, the junction area is smaller than that in the prior art. This reduces the junction capacitance of the manufactured transistor (semiconductor device).

The side wall film 9 is a laminated film including the silicon nitride film 12c and the silicon oxide film 14a. Part of the silicon nitride film 12c is arranged between the silicon oxide film 14a and the silicon film 5. Another part of the silicon nitride film 12c is arranged between the silicon oxide film 14a and the n-type diffusion layer 6. In this configuration, the diffusion of the impurities (boron (B)), which are included in the silicon film 5 (n-type diffusion layer 6), into the silicon oxide film 14a is prevented. Further, the concentration of impurities in the silicon film 5 (n-type diffusion layer 6) is maintained at a desired value. This obtains a transistor having the designed characteristics.

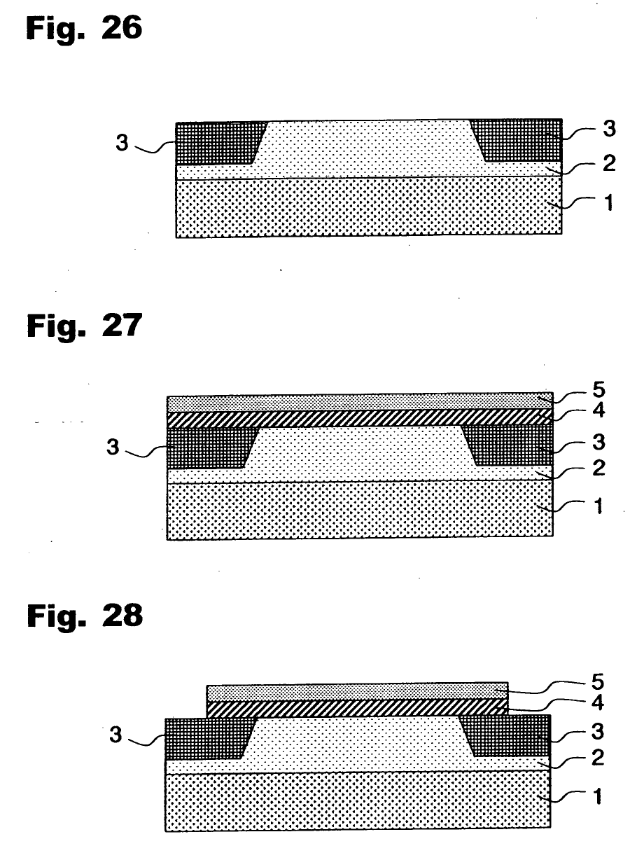

The procedures for manufacturing the semiconductor device according to the fourth embodiment of the present invention will now be discussed with reference to FIGS. 24 and 26 to 35.

[Process 1: FIG. 26] The element isolation film 3 is formed on the p-type silicon substrate 1 by performing, for example, STI. Then, n-type impurities are ion-implanted and activated to form the active region 2a (collector layer 2). For example, phosphorous (P) is implanted with an accelerating energy of approximately 500 to 4000 keV to obtain a concentration of about 3×10¹³ cm⁻² to 3×10¹⁵ cm⁻². Then, heat treatment is performed at a temperature of about 1000° C. Then, the collector layer 2 may be formed from the silicon epitaxial layer, which is doped with n-type impurities, and the element isolation film 3 may subsequently be formed through STI or the like).

[Process 2: FIG. 27] Low pressure chemical vapor deposition (CVD) is performed to epitaxially grow the silicon-germanium (SiGe) alloy layer 4, in which boron (B) is doped at a concentration of approximately 1×10¹⁹ cm⁻³. Further, the silicon film 5, which does not include germanium (Ge) is epitaxially grown. The SiGe alloy layer 4 and the silicon film 5 each have a thickness of approximately 40 nm, which is approximately 80 nm in total. Boron (B) is an example of a first impurity.

The Ge concentration in the SiGe alloy layer 4 may be uniform throughout the layer. Alternatively, the Ge concentration in the SiGe alloy layer 4 may have a gradient doping profile so that the Ge concentration gradually increases from the contact position with the silicon film 5 toward the collector layer 2. This would shorten the time electrons travel through the base and form a transistor that operates at high speeds. In such a case, it is preferred that the Ge concentration substantially be about 0% at the side contacting the silicon film 5 and about 15% to 20% at the side contacting the collector layer 2.

In the same manner as the SiGe alloy layer 4, the silicon film 5 is doped with boron (B).

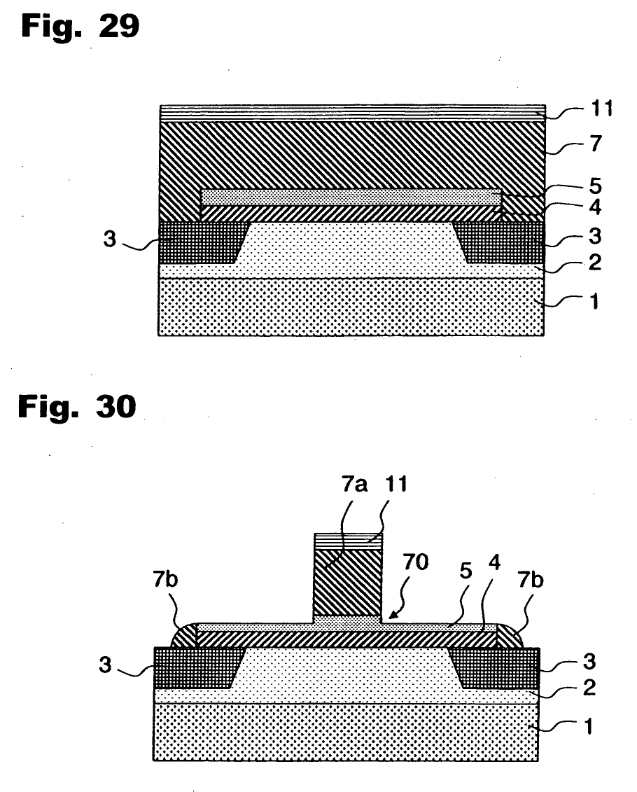

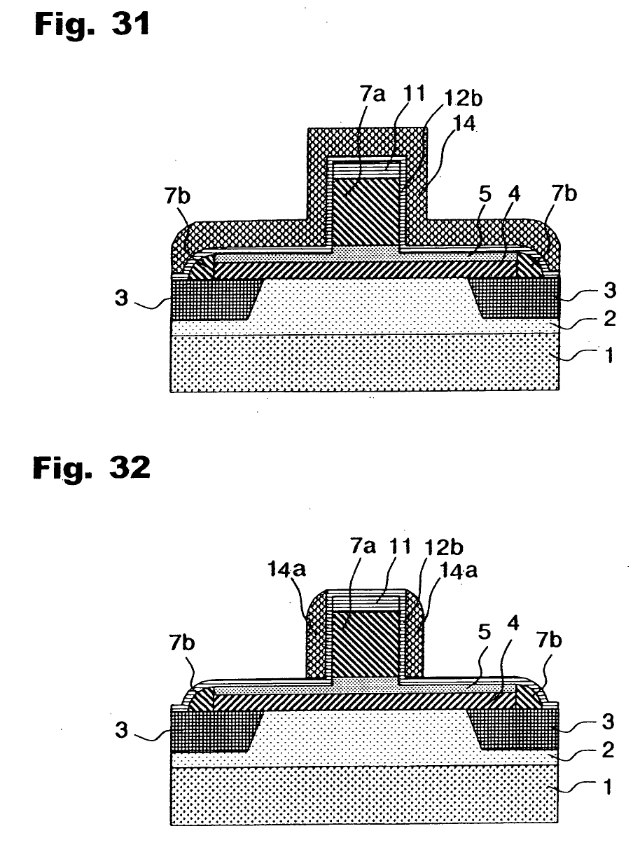

Prior to, subsequent to, or prior to and subsequent to the formation of the SiGe alloy layer 4, low pressure CVD may be performed to epitaxially grow a silicon film that does not include boron (B) or an SiGe alloy layer that does not include boron (B).

[Process 3: FIG. 28] Next, lithography is performed to form a resist pattern. Then, dry etching is performed using the resist pattern as a mask to remove unnecessary portions from the silicon film 5 and the SiGe alloy layer 4.

[Process 4: FIG. 29] Low pressure CVD is performed to form the polycrystalline silicon film 7, which is doped with n-type impurities of approximately 1×10²⁰ cm⁻³ or more. Further, the silicon nitride film 11 is formed. Examples of the n-type impurities are arsenic (As) and phosphorus (P). The thickness of the polycrystalline silicon film 7 is approximately 200 nm. The thickness of the silicon nitride film 11 is approximately 100 nm.

[Process 5: FIG. 30] Lithography is performed to form a resist pattern. Then, dry etching is performed using the resist pattern as a mask to sequentially remove the silicon nitride film 11, the polycrystalline silicon film 7, and the silicon film 5. In this process, dry etching is ended when part of the silicon film 5 is still remaining on the entire surface of the SiGe alloy layer 4, that is, before the silicon film 5 is completely removed. The polycrystalline silicon film 7 is processed to form the polycrystalline silicon film 7a, which functions as an emitter electrode, and the side wall film 7b, which surrounds the SiGe alloy layer 4 and the silicon film 5.

[Process 6: FIG. 31] CVD is performed to form a silicon nitride film 12b and a silicon oxide film 14. The silicon nitride film 12b is formed by, for example, heating a mixed gas of dichlorosilane (SiH₂Cl₂) and ammonia (NH₃) to have a thickness of approximately 10 nm. The silicon oxide film 14 is formed by, for example, heating a mixed gas of tetraethoxysilane (TEOS) and oxygen (O₂) under a temperature of 720° C. The thickness of the silicon oxide film is approximately 200 nm.

[Process 7: FIG. 32] Then, dry etching is performed to carry out complete surface etch back on the silicon oxide film 14 and form a silicon oxide film 14a, which is referred to as a side wall, around the silicon nitride film 11, the polycrystalline silicon film 7a, and the projecting portion of the silicon film 5. During dry etching, the etching selectivity of the silicon nitride film relative to the silicon oxide film is 10 or greater. Thus, the silicon nitride film 12b is not removed through the etching regardless of manufacturing differences when processing the silicon oxide film 14a. As a result, etching damages are not inflicted on the silicon nitride film 12b during the dry etching. Thus, the base layer is formed with its thickness controlled as designed.

[Process 8: FIG. 33] Boron (B) is ion-implanted and then activated by performing a heat treatment to form the p⁺ diffusion layer 10. The ion implantation is performed by, for example, implanting BF₂ at an amount of 1×10¹⁴ cm⁻² to 5×10¹⁵ cm⁻² with an accelerating energy of 1 keV to 30 keV. With this ion implantation condition, ions do not pass through the silicon nitride film 11, which is located on the polycrystalline silicon film 7a and which has a thickness of approximately 100 nm.

[Process 9: FIG. 34] Subsequently, heat treatment is performed to diffuse the n-type impurities of the polycrystalline silicon film 7a into the silicon film 5 to form the n-type diffusion layer 6. As a result, the emitter-base junction is formed in the silicon film 5. The heat treatment is performed with an RTA apparatus under a temperature of about 1050° C. for a period of 5 to 30 seconds.

The emitter layer (n-type diffusion layer 6) in the silicon film 5 is formed by diffusing the n-type impurities of the polycrystalline silicon film 7a. The impurities are diffused not only in the vertical direction towards the semiconductor substrate 1 but also in a horizontal direction parallel to the semiconductor substrate 1. Thus, the effective emitter width may become greater than the width of the polycrystalline silicon film 7a. However, in the fourth embodiment of the present invention, the contact surface 50 between the emitter layer (n-type diffusion layer 6) and the emitter electrode (polycrystalline silicon film 7a) is located above the lower surface 60 of the silicon nitride film 12b (the side wall film 9 in subsequent processes). Thus, the silicon nitride film 12b functions as a diffusion barrier wall of impurities to prevent the enlargement of the n-type diffusion layer 6 in the horizontal direction. This miniaturizes the width of the emitter layer.

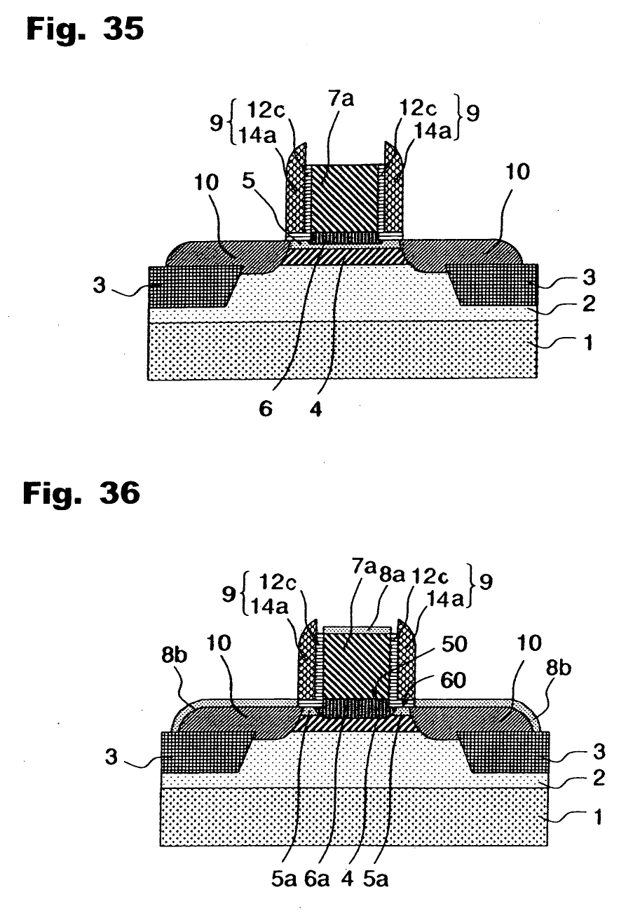

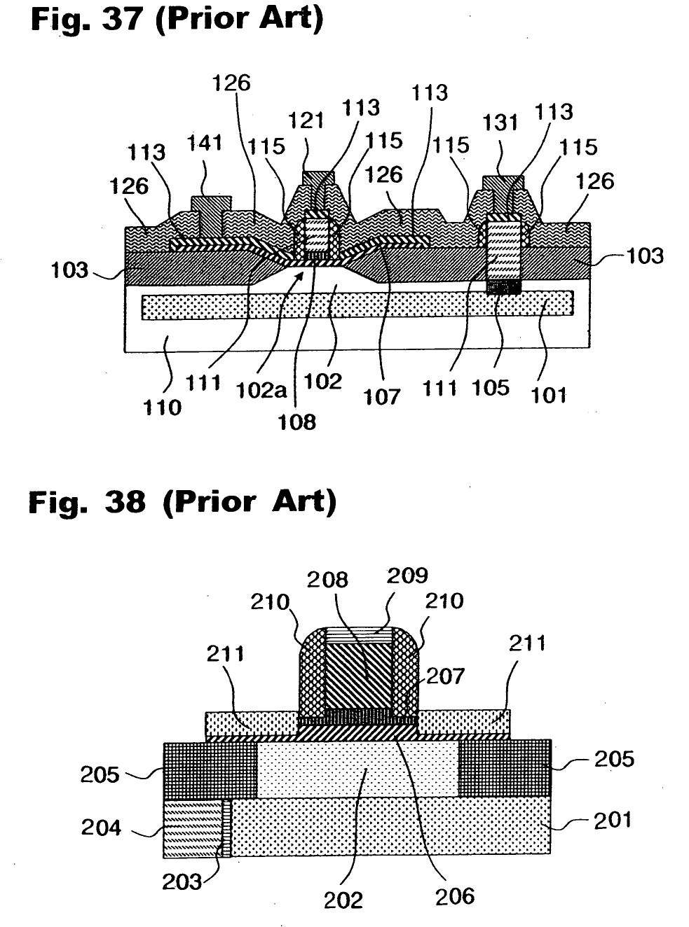

The silicon nitride film 12b is located between the silicon oxide film 14a, the silicon film 5, and the n-type diffusion layer 6. This prevents the impurities (boron (B)) included in the silicon film 5 and the n-type diffusion layer 6 from being diffused toward the silicon oxide film 14a. Thus, the desired impurity concentration is maintained for the silicon film 5 and the n-type diffusion layer 6, and the manufactured transistor has the designed characteristics.

[Process 10: FIG. 35] Subsequent to the heat treatment, the silicon nitride film 12b and the silicon nitride film 11 on the base electrode, the emitter electrode, and the collector electrode (not shown) are removed with phosphoric acid. This forms the side wall film 9, which includes the silicon nitride film 12c and the silicon oxide film 14a. The phosphoric acid processing is performed, for example, at a temperature of 160° C. for approximately 20 minutes. As a result, the silicon nitride film 12c is formed only between the silicon oxide film 14a, the silicon film 5, the n-type diffusion layer 6, and the polycrystalline silicon film 7a. The location of the silicon nitride film 12c between the silicon oxide film 14a, the silicon film 5, the n-type diffusion layer 6, and the polycrystalline silicon film 7a prevents the impurities of the silicon film 5 and the n-type diffusion layer 6 from being diffused into the silicon oxide film 14a even when heat treatment is performed. Thus, the desired impurity concentration is maintained for the silicon film 5 and the n-type diffusion layer 6, and the manufactured transistor has the designed characteristics.

[Process 11: FIG. 24] A cobalt (Co) layer is formed on the surface of the polycrystalline silicon film 7a and the surface of the p⁺ diffusion layer 10. The cobalt layer is heat treated to form cobalt silicide films (silicide films 8a and 8b). The sheet resistance of the silicide films 8a and 8b is approximately 5 Ω/square. The sheet resistance of the silicide films 8a and 8b is much smaller than the sheet resistance of the prior art p⁺-type SiGe layer (p⁺ diffusion layer 10) that is approximately 100 Ω/square. Thus, the silicide films 8a and 8b lower the parasitic resistance produced between the internal base layer and the base electrode (not shown), which is connected to the external base layer.

In the silicide processing, titanium (Ti) may be used in lieu of cobalt to form a titanium silicide film. This would have the same effects.

An interlayer insulation film, such as a plasma TEOS film, may be deposited on the surface of a semiconductor substrate. In this case, a contact hole is formed in a collector electrode, base electrode, and emitter electrode of an NPN transistor. Then, a conductive layer including a barrier metal layer, made of titanium or the like, and a conductive layer, made of aluminum or aluminum alloy, is formed. This manufactures a bipolar transistor having an NPN transistor.

An SiGe base heterojunction bipolar transistor according to a fifth embodiment of the present invention will now be described with reference to FIG. 36. The fourth embodiment differs from the fifth embodiment in that the lower surface of the n-type diffusion layer 6 contacts the SiGe alloy layer 4. That is, part of the n-type diffusion layer 6 is embedded in the SiGe alloy layer 4. The silicon film 5a is an example of a second region, and the n-type diffusion layer 6a is an example of a first region.

The contact between the lower surface of the n-type diffusion layer 6a and the SiGe alloy layer 4 reduces the distance between the lower surface of the n-type diffusion layer 4, which functions as an emitter layer, and the collector layer 2. This shortens the time electrons travel from the emitter layer to the collector layer 2. Accordingly, the fifth embodiment obtains a transistor having higher performance and enabling operation at higher speeds.

To manufacture the semiconductor device of the fifth embodiment, in process 2 of the fourth embodiment, low pressure CVD is performed to form a silicon film 5a having a thickness of approximately 30 nm. In process 9 of the fourth embodiment, heat treatment is performed with an RTA apparatus under a temperature of about 1050° C. for a period of approximately 5 seconds. As a result, the n-type impurities in the polycrystalline silicon film 7a are diffused toward the collector layer 2 for approximately 40 nm so as to pass through the silicon film 5a, which has a thickness of approximately 30 nm, and reach the SiGe alloy layer 4. In comparison to when the lower surface (emitter-base junction) of the n-type diffusion layer 6a does not reach the SiGe alloy layer 4 (i.e., when the lower surface of the diffusion layer 6a is in the silicon film 5a), the emitter injection efficiency is high and the current amplification rate is improved with the configuration of the semiconductor device of the fifth embodiment. This is because the band gap of the SiGe alloy layer is narrower than that of the silicon film when the lower surface of the n-type diffusion layer 6a is in the SiGe alloy layer 4. As a result, the height of the barrier wall for the electrons injected from the emitter layer to the base layer becomes lower in comparison to when the lower surface of the n-type diffusion layer 6a is in the silicon film 5a. Accordingly, the height of the barrier wall for the electrons injected from the emitter layer to the base layer becomes lower in comparison to the height of the barrier wall for the positive holes injected from the base layer to the emitter layer. This increases the emitter injection efficiency and realizes a high current amplification rate. Thus, the manufactured semiconductor device has high performance.

It should be apparent to those skilled in the art that the present invention may be embodied in many other specific forms without departing from the spirit or scope of the invention. Particularly, it should be understood that the present invention may be embodied in the following forms.

In each of the above embodiments, n-type is referred to as a first conductive type, and p-type is referred to as a second conductive type. However, p-type may be the first conductive type, and n-type may be the second conductive type.

In each of the above embodiments, the first alloy layer 4a, the second alloy layer 4b, and the p⁺ diffusion layer 10, which are examples of a base layer and external base layer, are not limited to a single SiGe layer and may be an Si/SiGe laminated layer or an Si/SiGe/Si laminated layer, in which an Si layer and an SiGe layer are laminated.

The present invention may be applied to various types of bipolar transistors. For example, the semiconductor substrate may be a gallium arsenide (AlGaAs) alloy. Such a transistor is a so-called AlGaAs base heterojunction bipolar transistor.

In each of the above embodiments, the impurity regions 20 and 20a are formed by ion-implanting boron (B) so as to reach the surface of the active region 2a. However, boron (B) may be implanted so that it does not reach the surface of the active region 2a. After the implantation, boron (B) may be thermally diffused so as to reach the surface of the active region 2a and form the impurity regions 20 and 20a.

The details of each process are not limited to the manner described in each of the above embodiments and may be altered.

The impurity regions 20 and 20a may include only n-type impurities or only p-type impurities as long as the conductivity of the impurity regions 20 and 20a is less than that of the active region 2a.

The present examples and embodiments are to be considered as illustrative and not restrictive, and the invention is not to be limited to the details given herein, but may be modified within the scope and equivalence of the appended claims.

What is claimed is:

1. A semiconductor device comprising:
a semiconductor substrate;
an element isolation film arranged on the semiconductor substrate;
an active region, surrounded by the element isolation film, for functioning as a collector layer;
a conductive layer, arranged on the active region, for functioning as a base layer;
an emitter layer arranged on a portion of the conductive layer;
an emitter electrode arranged on the emitter layer and having a side surface;
a first film covering the side surface of the emitter electrode;
a first impurity region, adjacent to the conductive layer, for functioning as an external base layer; and
a second impurity region formed in part of a surface of the active region and extending between the element isolation film and a portion of the conductive layer located below the emitter electrode, wherein:
the active region contains first conductive type impurities, and the first impurity region contains second conductive type impurities of a conductive type opposite to the first conductive type impurities; and
the second impurity region is of a conductive type that is the same as the first impurity region and has conductivity that is less than that of the first impurity region.

2. The semiconductor device according to claim 1, wherein a boundary between the first impurity region and the conductive layer is located above the second impurity region.

3. The semiconductor device according to claim 1, wherein the second impurity region contains impurities of different conductive types.

4. A semiconductor device comprising:
a semiconductor substrate;
an element isolation film arranged on the semiconductor substrate;
an active region, surrounded by the element isolation film, for functioning as a collector layer;
a conductive layer, arranged on the active region, for functioning as a base layer;
an emitter layer arranged on a portion of the conductive layer;
an emitter electrode arranged on the emitter layer and having a side surface;
a first film covering the side surface of the emitter electrode;
a first impurity region, adjacent to the conductive layer, for functioning as an external base layer; and
a second impurity region formed in part of a surface of the active region and extending between the element isolation film and a portion of the conductive layer located below the emitter electrode, wherein:
the active region contains first conductive type impurities, and the first impurity region contains second conductive type impurities of a conductive type opposite to the first conductive type impurities; and
the second impurity region is of a conductive type that is the same as the active region and has conductivity that is less than that of the active region.

5. The semiconductor device according to claim 4, wherein a boundary between the first impurity region and the conductive layer is located above the second impurity region.

6. The semiconductor device according to claim 4, wherein the second impurity region contains impurities of different conductive types.

7. A semiconductor device comprising:
a semiconductor substrate;
an element isolation film arranged on the semiconductor substrate;
an active region, surrounded by the element isolation film, for functioning as a collector layer;
a conductive layer, arranged on the active region, for functioning as a base layer;
an emitter layer arranged on a portion of the conductive layer;
an emitter electrode arranged on the emitter layer and having a side surface;
a first film covering the side surface of the emitter electrode;
a first impurity region, adjacent to the conductive layer, for functioning as an external base layer; and
a second impurity region formed in part of a surface of the active region and extending between the element isolation film and a portion of the conductive layer located below the emitter electrode, wherein:
the active region contains first conductive type impurities, and the conductive layer includes third conductive type impurities of a conductive type opposite to the first conductive type impurities; and
the second impurity region is of a conductive type that is the same as the conductive layer and has conductivity that is less than that of the conductive layer.

8. The semiconductor device according to claim 7, wherein:
the first impurity region contains second conductive type impurities of a conductive type opposite to the first conductive type impurities; and
the conductive layer includes a first conductive layer, arranged on the active region, and a second conductive layer, arranged on the second impurity region, the second conductive layer having conductivity that is greater than that of the first conductive layer and less than that of the first impurity region.

9. The semiconductor device according to claim 7, wherein the second impurity region contains impurities of different conductive types.

10. A semiconductor device comprising:
a semiconductor substrate;
an element isolation film arranged on the semiconductor substrate;
an active region, surrounded by the element isolation film, for functioning as a collector layer;
a conductive layer, arranged on the active region, for functioning as a base layer;
an emitter layer arranged on a portion of the conductive layer;
an emitter electrode arranged on the emitter layer and having a side surface;
a first film covering the side surface of the emitter electrode;
a first impurity region, adjacent to the conductive layer, for functioning as an external base layer; and
a second impurity region formed in part of a surface of the active region and extending between the element isolation film and a portion of the conductive layer located below the emitter electrode, wherein:
the active region contains first conductive type impurities, and the conductive layer includes third conductive type impurities of a conductive type opposite to the first conductive type impurities; and
the second impurity region is of a conductive type that is the same as the conductive layer and has conductivity that is less than that of the conductive layer.

11. The semiconductor device according to claim 10, wherein:
the first impurity region contains second conductive type impurities of a conductive type opposite to the first conductive type impurities;
the conductive layer includes a first conductive layer, arranged on the active region, and a second conductive layer, arranged on the second impurity region, the second conductive layer having conductivity that is greater than that of the first conductive layer and less than that of the first impurity region.

12. The semiconductor device according to claim 10, wherein the second impurity region contains impurities of different conductive types.

13. A semiconductor device comprising:
a semiconductor substrate;
an element isolation film arranged on the semiconductor substrate;
an active region of a first conductive type, surrounded by the element isolation film, for functioning as a collector layer;
an alloy layer of a second conductive type arranged on the active region;
an emitter layer of the first conductive type arranged on the alloy layer, wherein:
the alloy layer includes a first portion, arranged immediately below the emitter layer and functioning as a base layer, and a second portion, electrically connected to the base layer and functioning as an external base layer;
a surface of the active region includes an impurity region, which includes impurities of the second conductive type, and a region, which is surrounded by the impurity region and which contacts a lower surface of the base layer and which is free from impurities of the second conductive type.

14. The semiconductor device according to claim 13, wherein the impurity region is of the first conductive type and has conductivity that is less than that of the active region.

15. The semiconductor device according to claim 13, wherein the impurity region is of the second conductive type and has conductivity that is less than that of the external base layer.

16. The semiconductor device according to claim 13, wherein the impurity region contains impurities of the first conductive type and impurities of the second conductive type.

17. The semiconductor device according to claim 13, wherein a boundary between the base layer and the external base layer is located above the impurity region.

18. The semiconductor device according to claim 13, further comprising:
a layer arranged between the base layer and the external base layer and having conductivity that is greater than that of the base layer and less than that of the external base layer.

19. A method for manufacturing a semiconductor device, the method comprising:
preparing a semiconductor substrate and forming an active region of a first conductive type surrounded by an element isolation film on the semiconductor substrate;
forming an alloy layer of a second conductive type on the element isolation film and the active region;
forming an emitter electrode of a first conductive type on the alloy layer and above the active region;
implanting second conductive type impurities from above the emitter electrode and the alloy layer to selectively form an impurity region containing the second conductive type impurities in a surface of the active region at a portion excluding a portion located below the emitter electrode; and
diffusing first conductive type impurities included in the emitter electrode into a portion of the alloy layer to form an emitter layer.

20. The method according to claim 19, wherein the first conductive type impurities are diffused in a vertical direction directed toward the semiconductor substrate and a horizontal direction parallel to the semiconductor substrate, the first conductive type impurities being diffused in a diffusion range extending from a side surface of the emitter electrode in the horizontal direction for an extended length, the method further comprising:
forming an oxide film, having a thickness that is greater than the extended length, for covering the side surface of the emitter electrode prior to said implanting second conductive type impurities.

21. The method according to claim 19, further comprising:
forming an insulative film on the side surface of the emitter electrode subsequent to said implanting second conductive type impurities, said forming an emitter electrode being performed subsequent to said forming an insulative film and including implanting the first conductive type impurities so that the emitter layer does not reach the active region.

22. The method according to claim 19, further comprising:
forming an insulative film on the side surface of the emitter electrode prior to said implanting second conductive type impurities.

23. The method according to claim 20, further comprising:
forming an insulative film covering the side surface of the emitter electrode and having a thickness that is greater than the extended length.

24. A semiconductor device comprising:
a semiconductor substrate;
a collector layer formed on the semiconductor substrate;
a conductive layer formed on the collector layer and functioning as a base layer;
a silicon film arranged on the conductive layer and including first impurities, the silicon film including a first region and a second region excluding the first region;
an emitter electrode having a side surface and formed on the first region of the silicon film; and
a first film covering the side surface of the emitter electrode and having a lower surface, wherein:
the first region of the silicon film contacts the emitter electrode and functions as an emitter layer, the first region including a contact surface for contacting the emitter electrode, wherein the contact surface is located farther from the semiconductor substrate than the lower surface of the first film;
the second region of the silicon film is at least partially arranged between the conductive layer and the first film so as to contact both of the conductive layer and the first film; and
the first film is a laminated film including a silicon nitride film and a silicon oxide film, the silicon nitride film including a portion arranged between the silicon oxide film and the silicon film.

25. The semiconductor device according to claim 24, wherein the first region of the silicon film includes a surface adjacent to the side surface of the emitter electrode, the second region of the silicon film includes a surface adjacent to the surface of the first region, and the silicon nitride film is formed so as to span across the side surface of the emitter electrode, the surface of the first region, and the surface of the second region.

26. The semiconductor device according to claim 24, wherein the emitter electrode includes second conductive type impurities, and the first region is formed by thermally diffusing the second impurities from the emitter electrode into the silicon film.

27. The semiconductor device according to claim 24, wherein the conductive layer is a silicon-germanium alloy layer and includes a lower surface contacting the conductive layer.

28. The semiconductor device according to claim 24, wherein the portion of the silicon nitride film contacts both of the silicon oxide film and the silicon film.
